(19) United States
(12) Patent Application Publication
(10) Pub. No.: US 2022/0399514 A1
(43) Pub. Date: Dec. 15, 2022

(54) ORGANIC PHOTOVOLTAIC DEVICE VIA ULTRA-THIN SHADOW MASK DEVICE, SYSTEMS AND METHODS

(71) Applicant: The Regents of the University of Michigan, Ann Arbor, MI (US)

(72) Inventors: Stephen R. FORREST, Ann Arbor, MI (US); Dejiu FAN, Ann Arbor, MI (US); Xinjing Huang, Ann Arbor, MI (US)

(21) Appl. No.: 17/840,800

(22) Filed: Jun. 15, 2022

Related U.S. Application Data
(60) Provisional application No. 63/210,699, filed on Jun. 15, 2021.

(51) Int. Cl. H01L 51/44; H01L 27/30; H01L 51/42; H01L 51/00

(52) U.S. Cl. CPC H01L 51/445; H01L 27/301; H01L 51/4253; H01L 51/0071; H01L 51/0036

(57) ABSTRACT

An ultra-thin shadow mask comprises a plastic foil including a plurality of apertures, wherein the ultra-thin shadow mask is less than 25 μm thick, and wherein the ultra-thin shadow mask has a feature size of at least 1 μm to about 100 μm. An organic photovoltaic (OPV) device comprises a first electrode including a first grid structure, the first grid structure having a feature size of at least 1 μm to about 100 μm, a heterojunction under the first electrode, a second electrode under the heterojunction including a second grid structure, and a plurality of outcoupling layers over the first electrode. Related methods are also disclosed.

### CROSS-REFERENCE TO RELATED APPLICATIONS

This application claims priority to U.S. provisional application No. 63/210,699 filed on Jun. 15, 2021, incorporated herein by reference in its entirety.

### STATEMENT REGARDING FEDERALLY SPONSORED RESEARCH OR DEVELOPMENT

This invention was made with government support under DE-EE0008561 awarded by the U.S. Department of Energy. The government has certain rights in the invention.

### BACKGROUND OF THE INVENTION

Conventional photolithography patterning has realized ultrahigh resolution in the fabrication of electronic devices. However, the etching and solvent-assisted lift-off processes are not compatible with a majority of organic materials. Therefore, it is essential to develop a high-resolution patterning method that will not attack organic materials. Thus, there is a need in the art for improved high-resolution patterning methods and related devices.

### SUMMARY OF THE INVENTION

Some embodiments of the invention disclosed herein are set forth below, and any combination of these embodiments (or portions thereof) may be made to define another embodiment.

In one aspect, an ultra-thin shadow mask comprises a plastic foil including a plurality of apertures, wherein the ultra-thin shadow mask is less than 25 μm thick, and wherein the ultra-thin shadow mask has a feature size of between 1 μm and 100 μm.

In one embodiment, the plastic foil comprises Kapton. In one embodiment, the shadow mask is configured for patterning flexible devices.

In another aspect, an apparatus for patterning an electrode using an ultra-thin shadow mask comprises the ultra-thin shadow mask as described above, a substrate configured to have an electrode disposed thereon positioned below the ultra-thin shadow mask, and a patterning system including a material source and means for evaporating the material, positioned over the ultra-thin shadow mask, configured to pattern the electrode through the ultra-thin shadow mask.

In one embodiment, the patterning system comprises a photolithography device. In one embodiment, the plastic foil comprises Kapton.

In another aspect, an organic photovoltaic (OPV) device comprises at least one OPV cell comprising a first electrode including a first grid structure, the first grid structure having a feature size of between 1 μm and 100 μm, a heterojunction under the first electrode, a second electrode under the heterojunction including a second grid structure, and a plurality of outcoupling layers over the first electrode.

In one embodiment, the OPV device is semi-transparent. In one embodiment, the first grid structure is fabricated via the ultra-thin shadow mask. In one embodiment, the first electrode comprises an Ag layer about 16 nm thick. In one embodiment, the first grid structure comprises an Ag top grid having a grid width of between 5 μm and 50 μm, a grid separation of between 5 μm and 1000 μm, and a grid thickness of between 50 nm and 500 nm.

In one embodiment, the heterojunction comprises poly[4,8-bis(5-(2-ethylhexyl)thiophen-2yl)benzo[1,2-b:4,5-b′]dithiophene-co-3-fluorothieno[3,4-b]thio-phene-2-carboxylate] (PCE 10) and (4,4,10,10-tetrakis(4-hexylphenyl)-5,11-(2ethylhexyloxy)-4,10-dihydro-dithienyl[1,2-b:4,5b′]benzodithiophene-2,8-diyl)bis-(2-(3-oxo-2,3-dihydroinden-5,6-dichloro-1-ylidene)-malononitrile) (BT-CIC).

In one embodiment, the grid width is between 10 μm and 30 μm. In one embodiment, the grid thickness is between 50 nm and 150 nm. In one embodiment, the at least one OPV cell comprises a plurality of OPV cells arranged in a grid pattern. In one embodiment, the plurality of OPV cells are electrically connected in a series-parallel circuit layout. In one embodiment, the plurality of OPV cells are separated by an interconnection distance of 0.25 cm to 0.3 cm. In one embodiment, the first electrode is flexible.

In another aspect, an ultra-thin shadow mask fabrication method comprises attaching a plastic foil to a handle substrate via an elastomer layer positioned over the handle substrate, depositing a photoresist layer onto the plastic foil, patterning the photoresist layer, etching the plastic foil to create an ultra-thin shadow mask, wherein the ultra-thin shadow mask is less than 25 μm thick, removing the photoresist layer, and peeling the ultra-thin shadow mask off of the handle substrate.

In one embodiment, the method further comprises depositing a hard etching mask layer onto the plastic foil prior to the step of depositing a photoresist layer onto the plastic foil, patterning the hard etching mask layer with the photoresist layer, etching the plastic foil layer through the patterned hard etching mask layer to create the ultra-thin shadow mask, and removing the hard etching mask layer.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIGS. 1A and 1B show exemplary fabrication flows of a plastic shadow mask in accordance with some embodiments. The plastic foil is attached to a handle substrate via an elastomer layer and then etched through a photoresist mask (FIG. 1A) or an additional etching mask layer (FIG. 1B) to get the desired pattern. After the etching steps, the plastic foil is peeled off from the handle.

FIG. 2 shows an exemplary device structure of a 1 cm² ST-OPV device in accordance with some embodiments.

FIG. 3 shows exemplary current density-voltage (J-V) characteristics of 4 mm² (square), 1 cm² (circle) and 1 cm² anode with grids (triangle) ST-OPV devices under simulated 1 sun illumination in accordance with some embodiments.

FIG. 4 shows an exemplary schematic of the series-parallel connected module design in accordance with some embodiments.

FIGS. 5A through 5C show exemplary experimental results and an exemplary experimental device in accordance with some embodiments. FIG. 5A shows power conversion efficiencies of the separate unit cells across the module. FIG. 5B shows current-voltage (I-V) characteristics of a discrete cell (circle) and the module (square) under simulated 1 sun illumination. FIG. 5C shows a photograph of the ST-OPV module.

FIGS. 6A through 6C show exemplary experimental results in accordance with some embodiments. FIG. 6A shows current density-voltage (J-V) characteristics of 4 mm² (red, square), 1 cm² (blue, circle). and 1 cm² cathode with grids (yellow, triangle) OPV devices. FIG. 6B shows J-V characteristics of 4 mm² (red, square), 1 cm² (blue, circle) and 1 cm² anode with grids (yellow, triangle) ST-OPV devices. FIG. 6C shows J-V characteristics and FIG. 6D shows external quantum efficiency (EQE) spectra of 1 cm² ST-OPV cells with (blue, circles) and without (red, squares) the OC structure. FIG. 6E shows Transmission and reflection spectra of the ST-OPV stack with (blue, circles) and without (red, squares) the OC structure.

FIG. 7 is a table summarizing exemplary experimental results in accordance with some embodiments.

### DETAILED DESCRIPTION OF THE INVENTION

It is to be understood that the figures and descriptions of the present invention have been simplified to illustrate elements that are relevant for a clearer comprehension of the present invention, while eliminating, for the purpose of clarity, many other elements found in systems and methods of organic photovoltaic devices via ultra-thin shadow mask devices. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Ranges: throughout this disclosure, various aspects of the invention can be presented in a range format. It should be understood that the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

Referring now in detail to the drawings, in which like reference numerals indicate like parts or elements throughout the several views, in various embodiments, presented herein are organic photovoltaic devices via ultra-thin shadow mask devices, systems and methods.

Various non-limiting examples of OPVs and compositions within various layers of an OPV are described in greater detail below.

### Definitions

As used herein, the terms “electrode” and “contact” may refer to a layer that provides a medium for delivering photo-generated current to an external circuit or providing a bias current or voltage to the device. That is, an electrode, or contact, provides the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to a medium that permits the incident electromagnetic radiation in visible wavelengths to be transmitted through it. In some instances, the term “transparent” may be used with reference to one or more specific wavelengths or wavelength ranges of electromagnetic radiation, for example “transparent to green light” or “transparent to near infrared light.” As would be understood in the art, such use indicates that the medium permits the incident electromagnetic radiation in the indicated wavelength range to be transmitted through it.

As used herein, the term “semi-transparent” may refer to a medium that permits some, but less than 100% transmission of ambient electromagnetic radiation in one or more wavelength ranges. The electromagnetic radiation not transmitted may be reflected or absorbed by the medium or a component of the medium.

As used and depicted herein, a “layer” refers to a member or component of a photosensitive device whose primary dimension is X-Y, i.e., along its length and width. It should be understood that the term layer is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) or material(s).

As used herein, a “photoactive region” refers to a region of the device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Because ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, the term “band gap” (E_{g}) of a polymer may refer to the energy difference between the HOMO and the LUMO. The band gap is typically reported in electronvolts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M*+M), where M⁺ and M⁻ are the total energy of a positively and negatively charged molecule, respectively; M* and M are the molecular energy at the first singlet state (Si) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy E_{B} for the acceptor molecule leads to an increase of hole escape yield for the same HOMO offset between donor and acceptor molecules.

As used herein, “power conversion efficiency” (PCE) (η_{ρ}) may be expressed as:

$${η}_{ρ} = \frac{{V}_{OC} * FF * {J}_{SC}}{{P}_{O}} \qquad ( 1 )$$

where V_{OC} is the open circuit voltage, FF is the fill factor, J_{SC} is the short circuit current, and P_{O} is the input optical power.

As used herein, “spin coating” may refer to the process of solution depositing a layer or film of one or more materials (i.e., the coating materials) on a surface of an adjacent substrate or layer of material. The spin coating process may include applying a small amount of the coating material on the center of the substrate, which is either spinning at low speed or not spinning at all. The substrate is then rotated at high speed in order to spread the coating material by centrifugal force. Rotation is continued while the fluid spins off the edges of the substrate, until the desired thickness of the film is achieved. The applied solvent is usually volatile, and simultaneously evaporates. Therefore, the higher the angular speed of spinning, the thinner the film. The thickness of the film also depends on the viscosity and concentration of the solution and the solvent.

As used herein, the average photopic transmission (APT) may be calculated using the formula:

$$A P T = \frac{\int T ( λ ) P ( λ ) S ( λ ) d λ}{\int P ( λ ) S ( λ ) d λ} \qquad ( 2 )$$

where λ is wavelength, T is the transmission, P is the photopic spectral response of the human eye, and S is the AM 1.5G solar irradiance, which is the incident light spectrum of a solar cell. APT is also referred to as average visible transmission (AVT) in other semi-transparent work.

### Organic Photovoltaic Cells

As disclosed herein, various compositions or molecules may be provided within a solar cell or organic photovoltaic (OPV) cell. As supported by the Example section below, the various compositions or molecules for a semi-transparent OPV (ST-OPV) cell disclosed herein may be advantageous in providing one or more improvements over conventionally known ST-OPV cells. Such ST-OPVs may be integrated within a window pane to improve energy harvesting of solar irradiation. Reducing visible reflection and absorption are important to maximizing transmission and light utilization efficiency (LUE), which is the product of the power conversion efficiency and the average photonic transparency.

For example, the various OPV cell layers and devices disclosed herein may provide semi-transparent OPV cells (ST-OPVs) and devices having improved visible transmission and LUE over conventionally known ST-OPVs. Moreover, neutral and multi-colored ST-OPVs incorporating multilayer coatings may provide a wide variety of transmission colors (e.g., blue, green and red) with high efficiencies.

As disclosed herein, the improved semi-transparent OPV cells (ST-OPVs) and devices may include: an optical outcoupling (OC) layer, a first electrode, an active region or layer, a second electrode, and an anti-reflection coating (ARC) layer. Additional or fewer layers may be included as well.

The presence of the OC and/or ARC layer may enhance visible transmission within the ST-OPV cell while reflecting the near-infrared (NIR) light back into the cell. This may improve (e.g., double) the light utilization efficiency (LUE) when compared with a reference cell lacking the OC and ARC layers. In certain examples disclosed herein, the maximum LUE is at least 2.5%, at least 3%, at least 3.25%, at least 3.5%, at least 3.55%, or about 3.56% for an efficiency of at least 5.0%, at least 6.0%, at least 7.0%, or at least 8.0% at 1 sun, AM1.5G simulated emission is achievable.

A critical step in the fabrication of organic electronic devices is high-resolution patterning of organic or electrode materials. Although conventional photolithography patterning techniques have realized ultrahigh resolution, the etching or solvent-assisted lift-off processes may attack the vast majority of organic materials. Disclosed herein is an OPV fabrication method including the fabrication and use of an ultra-thin plastic shadow mask, which combines the high resolution of photolithography with the shadow mask patterning technique and provides for an easy and dry shadow mask patterning technique. The plastic shadow mask allows for feature sizes at lithography resolution, and the ultra-thin thickness minimizes the shadowing effect during non-conformal coating (e.g., evaporation). The thin mask thickness minimizes the shadowing effect during deposition and the plastic material is compatible with patterning on flexible substrates. Furthermore, the plastic shadow mask is also compatible with flexible device patterning, which is a promising application in the field of organic electronics. This technology has applications in high resolution OLED displays, high geometric fill factor OPVs, and narrow gate OTFTs.

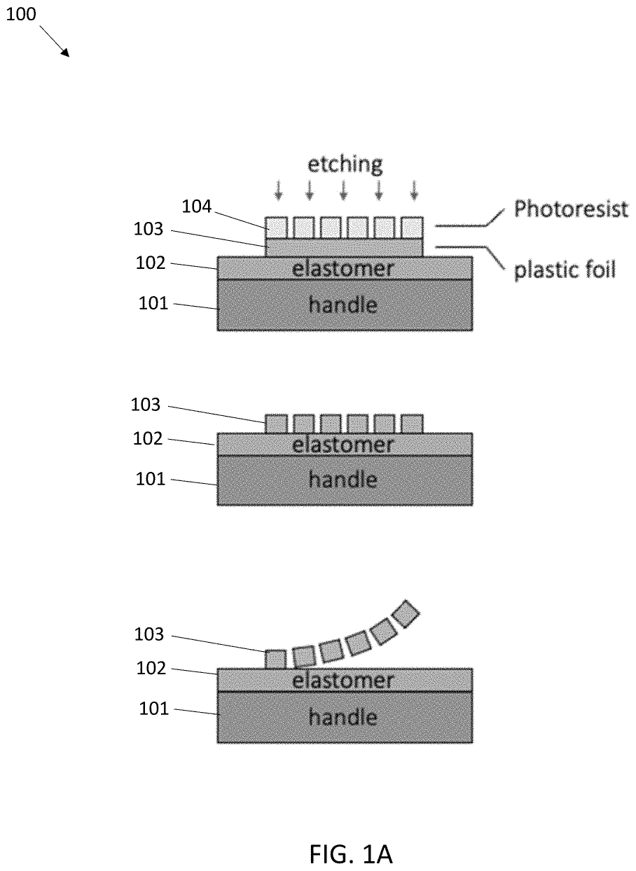

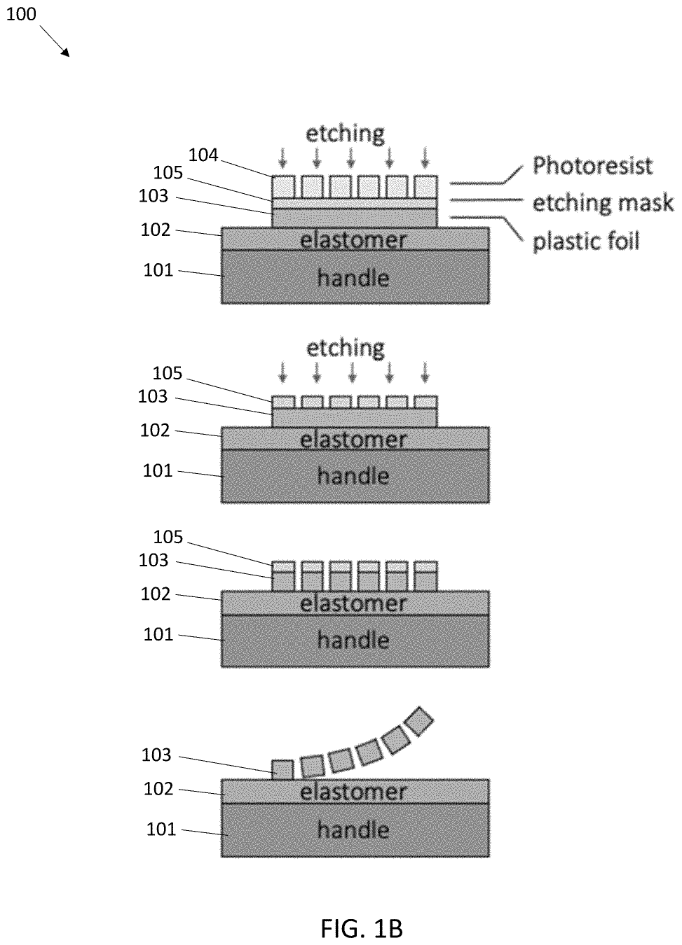

An example fabrication flow of a plastic shadow mask is illustrated in FIGS. 1A and 1B. As shown in FIGS. 1A and 1B, the plastic foil 103 (e.g., Kapton) is attached to a handle substrate 101 (e.g., Si) via an elastomer layer 102 (e.g., polydimethylsiloxane (PDMS)). The elastomer layer 102 ensures the intimate contact between plastic foil 103 and the handle 101, and the adhesion-free nature of the elastomer material also allows for an easy peel off without mechanical deformation of the plastic foil 103 after all of the fabrication steps. In FIG. 1A the photoresist layer 104 is then deposited onto the plastic foil 103 and patterned with conventional photolithography steps, followed by the etching process on the plastic foil 103.

FIG. 1B shows an alternative example for extra etching time. One example is when the etching rate is similar for the photoresist 104 and the plastic 103 while the thickness of photoresist 104 is thinner. An additional hard etching mask 105 (e.g., Al) can be inserted between photoresist layer 104 and plastic foil 103. The etching mask layer 105 is patterned with the photoresist 104, and the plastic foil 103 is then etched through the pattern of the mask layer 105. After the etching steps, the etching mask layer 105 is removed and the plastic shadow mask 103 can be peeled off from the handle 101.

In some embodiments, an ultra-thin shadow mask fabrication method comprises attaching a plastic foil 103 to a handle substrate 101 via an elastomer layer 102 positioned over the handle substrate 101, depositing a photoresist layer 104 onto the plastic foil 103, patterning the photoresist layer 104, etching the plastic foil 103 to create an ultra-thin shadow mask 103, removing the photoresist layer 104, and peeling the ultra-thin shadow mask off of the handle substrate 101. In some embodiments, the ultra-thin shadow mask 103 is less than 25 μm thick.

In some embodiments, the method further comprises depositing a hard etching mask layer 105 onto the plastic foil 103 prior to the step of depositing a photoresist layer 104 onto the plastic foil 103, patterning the hard etching mask layer 105 with the photoresist layer 104, etching the plastic foil layer 103 through the patterned hard etching mask layer 105 to create the ultra-thin shadow mask 103, and removing the hard etching mask layer 105.

In some embodiments, the ultra-thin shadow mask 103 comprises a plastic foil including a plurality of apertures. In some embodiments, the ultra-thin shadow mask 103 has a feature size of at least 1 μm to about 100 μm. In some embodiments, the ultra-thin shadow mask 103 is less than 25 μm thick. In some embodiments, the plastic foil 103 comprises Kapton. In some embodiments, the shadow mask 103 is configured for patterning flexible devices.

In some embodiments, an apparatus for patterning an electrode using an ultra-thin shadow mask comprises the ultra-thin shadow mask 103 as described above, a substrate configured to have an electrode disposed thereon positioned below the ultra-thin shadow mask, and a patterning system including a material source and means for evaporating the material, positioned over the ultra-thin shadow mask 103, configured to pattern the electrode through the ultra-thin shadow mask 103.

In some embodiments, the patterning system comprises a photolithography device. In some embodiments, the plastic foil 103 comprises Kapton.

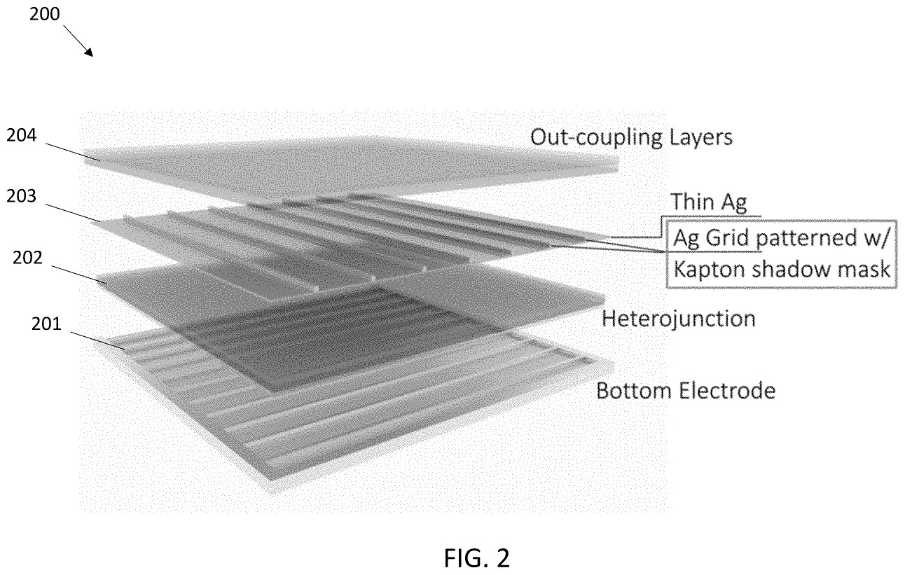

FIG. 2 depicts an exemplary organic photovoltaic (OPV) device 200. The OPV device 200 includes a first electrode 203 including a first grid structure, a heterojunction 202 under the first electrode 203, a second electrode 201 under the heterojunction 202 including a second grid structure, and a plurality of outcoupling layers 204 over the first electrode 203. In some embodiments the first grid structure has a feature size of at least 1 μm to about 100 μm. In some embodiments, the OPV device 200 comprises an OPV cell.

In some embodiments, the OPV device 200 is semi-transparent. In some embodiments, one or more or all layers of the OPV device 200 are transparent, for example transparent to visible light. In some embodiments, the first grid structure is fabricated via the ultra-thin shadow mask as described in FIGS. 1A and 1B. In some embodiments, the first electrode comprises an Ag layer about 16 nm thick. In some embodiments, the first grid structure comprises an Ag top grid having a grid width of between 5 μm and 50 μm, a grid separation of between 5 μm and 1000 μm, and a grid thickness of between 50 nm and 500 nm.

In some embodiments, the heterojunction comprises poly[4,8-bis(5-(2-ethylhexyl)thiophen-2yl)benzo[1,2-b:4,5-b′]dithiophene-co-3-fluorothieno[3,4-b]thio-phene-2-carboxylate] (PCE 10) and (4,4,10, 10-tetrakis(4-hexylphenyl)-5,11-(2ethylhexyloxy)-4,10-dihydro-dithienyl[1,2-b:4,5b′]benzodithiophene-2,8-diyl)bis-(2-(3-oxo-2,3-dihydroinden-5,6-dichloro-1-ylidene)-malononitrile) (BT-CIC).

In some embodiments the grid width is between 10 μm and 30 μm. In some embodiments, the grid thickness is between 50 nm and 150 nm. In some embodiments, the first electrode is flexible.

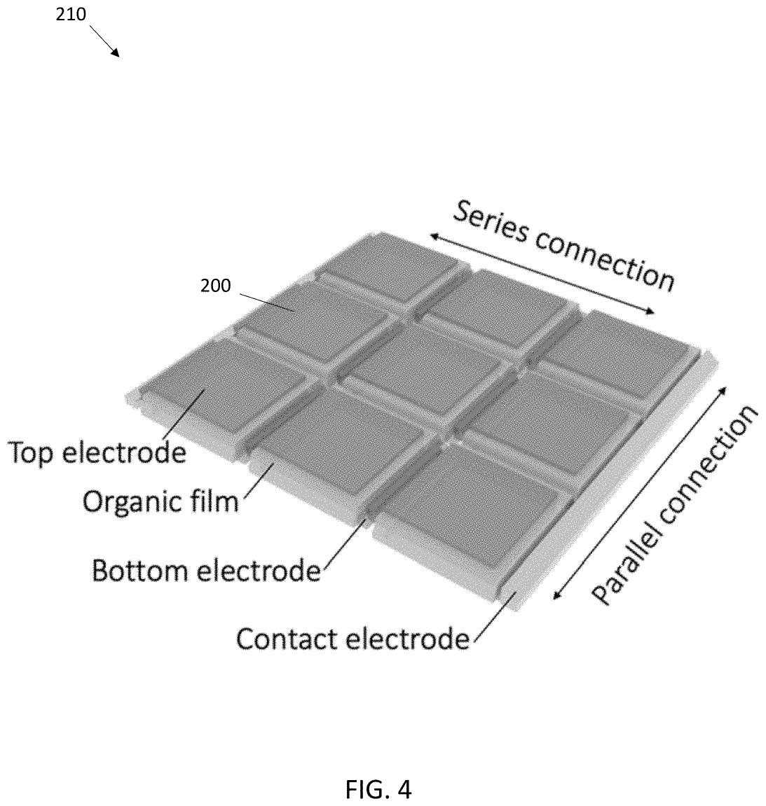

In some embodiments, a plurality of OPV cells 200 are arranged in a grid pattern to form an OPV device 210 as shown in FIG. 4. In some embodiments, the plurality of OPV cells 210 are electrically connected in a series-parallel circuit layout. In some embodiments, the plurality of OPV cells 210 are separated by an interconnection distance of about 0.25 cm to about 0.3 cm.

In some examples, the first electrode 203 and/or the second electrode 201 may include a conductive metal oxide, in some embodiments a transparent or semi-transparent conductive metal oxide, such as indium tin oxide (ITO), tin oxide (TiO), gallium indium tin oxide (GaITO), zinc oxide (ZnO), or zinc indium tin oxide (ZnITO). In other examples, the first electrode 203 and/or the second electrode 201 may include a thin metal layer, wherein the metal is selected from the group consisting of Ag, Au, Pd, Pt, Ti, V, Zn, Sn, Al, Co, Ni, Cu, Cr, or combinations thereof. In yet other examples, the first electrode 203 and/or the second electrode 201 may include a conductive polymer, in some embodiments a transparent or semi-transparent conductive polymer, such as polyanaline (PANI), or 3,4-polyethyl-enedioxythiophene:polystyrenesulfonate (PEDOT:PSS).

In some examples, first electrode 203 includes a first metal and a second metal, each having a volumetric concentration. In some embodiments, the volumetric concentration of the first metal in the electrode is roughly equal to the volumetric concentration of the second metal. In some embodiments, the volumetric concentration of the first metal is at least 2 times the volumetric concentration of the second metal. In other embodiments, the volumetric concentration of the first metal may be at least 5 times, at least 10 times, at least 20 times, at least 30 times, at least 40 times, at least 50 times, at least 75 times, or at least 100 times the volumetric concentration of the second metal. Volumetric concentration may be varied, for example, by varying the deposition rates of the two metals. For example, a volumetric concentration of 50:1 may be achieved in some embodiments by depositing the first metal at a first deposition rate at least 50 times the second deposition rate of the second metal. In one embodiment, the first deposition rate of the first metal is at least 0.2 nm/s, at least 0.5 nm/s, at least 0.7 nm/s, at least 0.8 nm/s, at least 0.9 nm/s, or at least 1 nm/s. The second deposition rate of the second metal may in some embodiments be at most at most 0.001 nm/s, at most 0.005 nm/s, at most 0.01 nm/s, at most 0.02 nm/s, at most 0.05 nm/s, at most 0.1 nm/s, or at most 0.5 nm/s.

In other examples, the first electrode 203 is an ultrathin metal film including silver. In some examples, the first electrode includes silver and at least one additional metal element such as copper, aluminum, nickel, titanium, gold, or a combination thereof. In certain examples, the weight percent amount of the additional metal element is less than 25 wt %, less than 20 wt %, less than 15 wt %, less than 10 wt %, less than 5 wt %, or less than 1 wt % of the first electrode metal film composition.

The second electrode 201 may include a conducting oxide, thin metal layer, or conducting polymer similar or different from the materials discussed above for the first electrode 203. In one particular example, the second electrode 203, which in some embodiments is a cathode, includes ITO.

As noted above, at least one active region or heterojunction layer 202 is present between the two electrodes 203, 201. The thickness of the active layer 202 may be variable. In certain examples, the thickness of the active layer 202 may be between 0.1 nm and 1 μm, or between 0.1 nm and 500 nm, or between 1 nm and 200 nm, or between 1 nm and 100 nm, or less than 100 nm, or in a range of 10-100 nm, 50-100 nm, or 60-90 nm. In some embodiments the thickness of the active layer 202 is about 85 nm.

The active region or heterojunction layer 202 positioned between the electrodes includes one or more compositions or molecules having an acceptor and a donor. In certain examples, the composition may be arranged as an acceptor-donor-acceptor (A-D-A′) or donor-acceptor-acceptor (d-a-a′). In other embodiments, more or fewer donors or more or fewer acceptors may be used.

As noted above, the OPV 200 may include an outcoupling (OC) layer 204 positioned above an electrode (e.g., the first electrode 203) such that the electrode is positioned between the outcoupling layer 204 and the active layer 202. The outcoupling layer 204 may provide an external coating to a surface of the OPV device 200 (e.g., by coating the surface of the first electrode).

The outcoupling layer 204 may be advantageous in improving or enhancing transmission of visible light. The OC layer 204 may also be configured to reflect or recycle near-infrared (NIR) light for absorption within the active layer.

In certain examples, the OC layer 202 is configured to enhance transmission within a specific wavelength range of visible light (e.g., visible light within 400-500 nm wavelength, 500-600 nm wavelength, 600-700 nm wavelength, 400-600 nm wavelength, 380-750 nm wavelength, or 500-700 nm wavelength). In some examples, the OC layer 202 is configured to enhance transmission within a specific color spectrum of visible light (e.g., violet light within 380-450 nm wavelength, blue light within 450-495 nm wavelength, green light within 495-570 nm wavelength, yellow light within 570-590 nm wavelength, orange light within 590-620 nm wavelength, or red light within 620-750 nm wavelength).

The OC layer 204 may be a multi-layer composition having one or more alternating metal compound sublayers and carbazole derivative sublayers. A metal compound sublayer may include magnesium fluoride. A carbazole derivative sublayer may include 4,4′-Bis(N-carbazolyl)-1,1′-biphenyl (CBP). In one example, the OC layer 204 may include a plurality of sublayers (e.g., four sublayers), alternating between a carbazole derivative such as CBP (index of refraction, nCBP=1.90±0.03) and a metal compound sublayer such as MgF₂ (nMgF₂=1.38±0.01). The CBP/MgF₂ multi-layer outcoupling coating layer may deposited onto the electrode surface. The OC layer 204 may have an overall thickness in a range of 1 nm to 1 μm, 1 nm to 500 nm, 10 nm to 400 nm, 100 nm to 300 nm, 100 nm to 200 nm, or 200 nm to 300 nm.

In certain examples, each individual metal compound (e.g., magnesium fluoride) sublayer in the plurality of sublayers has a thickness in a range of 1-300 nm, 10-200 nm, 10-100 nm, 100-200 nm, 10-50 nm, 50-150 nm, or 100-150 nm. In certain examples, the OC layer has a plurality of metal compound sublayers, and a first metal compound sublayer has a thickness in a range of 10-100 nm, and a second metal compound sublayer has a thickness in a range of 50-150 nm. In various embodiments, individual metal compound sublayers within the OC layer may have about the same thickness as one another or one or more metal compound sublayers may have a thickness different from the others.

In certain examples, each individual carbazole derivative (e.g., CBP) sublayer in the plurality of sublayers has a thickness in a range of 0.1 nm-1 μm, 1-500 nm, 1-300 nm, 1-200 nm, 10-100 nm, 100-200 nm, 10-50 nm, or 50-100 nm. In certain examples, the OC layer has a plurality of carbazole derivative sublayers, and a first carbazole derivative sublayer has a thickness in a range of 10-50 nm, and a second carbazole derivative sublayer has a thickness in a range of 50-100 nm.

The various thicknesses and compositions within the sublayers of the OC layer are advantageous in providing resonances within the sublayers and enhancing visible light transmission through the ST-OPV within a specific wavelength range. Adjustments to the thicknesses of the overall OC layer as well as the individual sublayers (e.g., the magnesium fluoride and CBP sublayers) within the plurality of sublayers of the OC coating layer 204 may alter the transmission of visible light (or a portion of visible light). In certain examples, the thickness of the OC layer and various sublayers may be configured to provide the transmission of monochromatic light.

### EXPERIMENTAL EXAMPLES

The invention is now described with reference to the following Examples. These Examples are provided for the purpose of illustration only and the invention should in no way be construed as being limited to these Examples, but rather should be construed to encompass any and all variations which become evident as a result of the teaching provided herein.

Without further description, it is believed that one of ordinary skill in the art can, using the preceding description and the following illustrative examples, make and utilize the present invention and practice the claimed methods. The following working examples therefore, specifically point out exemplary embodiments of the present invention, and are not to be construed as limiting in any way the remainder of the disclosure.

To demonstrate the feasibility of patterning organic electronic devices with a plastic shadow mask, a semi-transparent organic photovoltaic (ST-OPV) mini-module was made whose top electrode was patterned through a 25 μm thick Kapton shadow mask.

FIG. 2 shows the device structure of a 1 cm² ST-OPV device 200. The top electrode 203 included a 16 nm thin Ag layer with a 100 nm thick Ag top grids structure with 20 μm grid width and 600 μm separation patterned through the Kapton shadow mask.

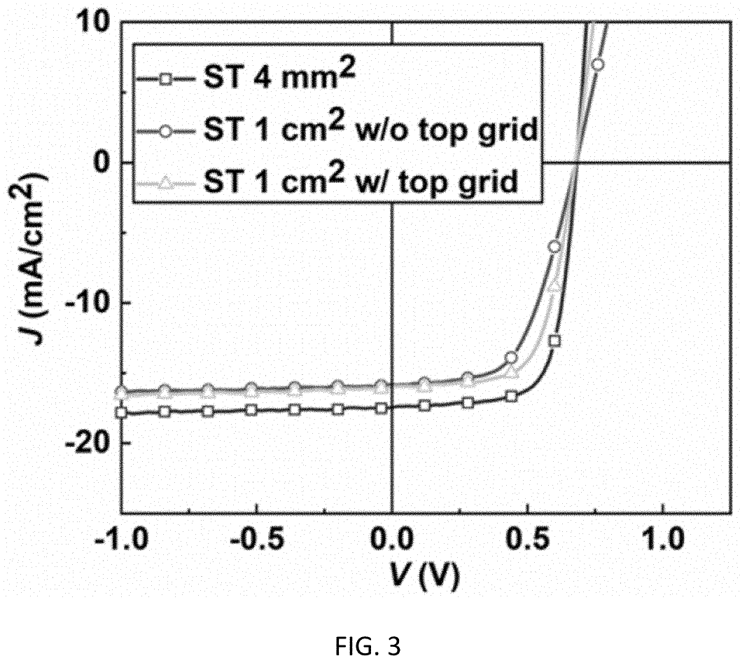

As illustrated in FIG. 3, compared to a 1 cm² device without the top electrode grids (line with circles), the one with the top grids (line with triangles) shows significantly reduced specific series resistance (RSA) from 9.5±0.3 Ω·cm² to 4.3±0.2 Ω·cm², which leads to an increase in fill factor (FF) from 0.57±0.01 to 0.65±0.01, and a power conversion efficiency (PCE) from 6.3±0.2% to 7.3±0.1%, which is only 10% loss compared to PCE=8.2±0.3% of 4 mm² device (line with squares).

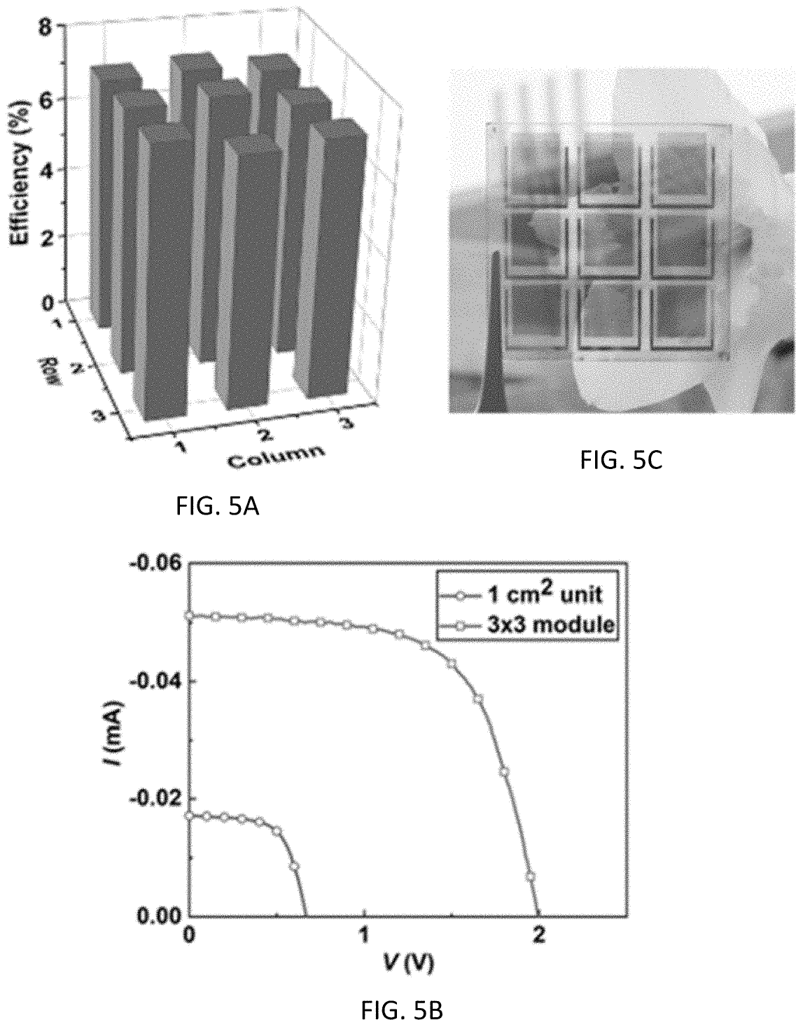

Nine of such 1 cm² ST-OPV devices 200 were then connected in a series-parallel circuit layout to construct a mini-module 210, as shown in FIG. 4. The fabrication yield of discrete cells was 100% and the PCE of the discrete cells ranges within 7.2±0.2%, as shown in FIG. 5A. FIG. 5B shows the current-voltage (IV) characteristics of a discrete cell and the module, where the module exhibits PCE=7.2±0.1% under simulated AM 1.5G illumination. The module PCE and FF is the same as for the discrete cells, indicating that the resistance losses from electrodes and interconnections are minimal due to the metal girds. In the photo of the module shown in FIG. 5C, the grid lines are almost invisible to human eyes due to the ultrafine top grids patterning realized by the Kapton shadow mask.

Semi-transparent organic photovoltaic (ST-OPV) cells are regarded as an attractive solution to building-integrated solar energy harvesting. Both the power conversion efficiency (PCE) and average photopic transmission (APT) of ST-OPVs have shown substantial increases in recent years. However, less attention has been paid to the area scaling of ST-OPV cells. The scalability of ST-OPV cells was investigated from 4 mm² to 1 cm², as well as 9 cm² active area prototype module. By integrating both top and bottom metal grids onto the transparent electrodes, the series resistance loss of 1 cm² ST-OPV cell was significantly reduced and was comparable to that of the grid-free 4 mm² cell. Nine 1 cm² cells were then connected in a series-parallel circuit to realize a prototype ST-OPV module. A 100% fabrication yield with only 5% PCE deviation among discrete cells was achieved. The semitransparent module shows PCE=7.2±0.1% under simulated AM 1.5G illumination at 1 sun intensity, which exhibits no connection resistance loss compared to that of the individual cells. The ST-OPV module exhibits an APT=38.1±1.1%, which enables a light utilization efficiency of LUE=2.74±0.09%. The method demonstrates a promising way for ST-OPV modules to scale without compromising performance.

Building integrated photovoltaics (BIPV) that employ transparent solar cells on window panes provide a space-efficient and attractive solution to solar energy harvesting. Unlike conventional inorganic semiconductors, organic semiconductors have relatively narrow excitonic absorption spectra that allow for organic photovoltaics (OPV) featuring transparency across visible spectrum, while selectively absorbing in the near-infrared (NIR). In this regard, OPVs are an attractive BIPV technology that can simultaneously achieve a high power conversion efficiency (PCE) along with a high average photopic transmission (APT). Over the past few years, OPVs have been demonstrated with impressive PCE and exceptional intrinsic stability. Furthermore, with the development of NIR-absorbing materials and optical structures, semitransparent OPVs (ST-OPVs) have realized remarkable improvements in light utilization efficiency (LUE=PCE×APT) up to 5.0%. Starting from this promising performance, an estimated cost of 0.47-1.6 $/Wp has been reported, which motivates practical and widespread deployment of ST-OPVs in BIPV applications.

It remains questionable, however, whether these highly efficient laboratory-scale, small area ST-OPVs can maintain their performance when translated to larger modules. To date, research on OPV modules has primarily focused on multi-junction strategies and improved material design in opaque devices, while less attention has been paid to the scalability of ST-OPVs. Compared to opaque OPVs with one thick, highly conductive metal electrode, ST-OPVs require both electrodes to be transparent, which doubles the overall series resistance loss, and significantly limits their scalability. Moreover, the narrow energy gaps of NIR absorbing materials required in ST-OPVs result in a low open-circuit voltage (VOC), which worsens series resistance losses by reducing the fill factor (FF) and, ultimately, the PCE.

Demonstrated herein is a scalable ST-OPV prototype module with a negligible compromise of efficiency from series resistance losses. The ST-OPVs employ bulk heterojunction (BHJ) based on a low energy gap polymer donor, poly[4,8-bis(5-(2-ethylhexyl)thiophen-2yl)benzo[1,2-b:4,5-b′]dithiophene-co-3fluorothieno[3,4-b]thio-phene-2-carboxylate] (PCE 10), combined with a NIR absorbing acceptor, (4,4,10,10-tetrakis(4-hexylphenyl)-5,11-(2ethylhexyloxy)-4,10-dihydro-dithienyl[1,2-b:4,5b′]benzodithiophene-2,8-diyl)bis-(2-(3-oxo-2,3-dihydroinden-5,6-dichloro-1-ylidene)-malononitrile) (BT-CIC). As the active area of the cells scale from 4 mm² to 1 cm², the sheet resistance of the indium tin oxide (ITO) cathode and the thin, semitransparent Ag anode dominates the specific series resistance (RSA), which reduces the FF and PCE. By employing finely patterned metal grids on the two transparent electrodes, the series resistance loss of the 1 cm² device is significantly reduced, leading to an improved PCE close to that of a 4 mm² device. Based on these findings, nine 1 cm² ST-OPV devices were integrated into a prototype module and connected in a series-parallel circuit configuration with a geometric fill factor (GFF) of 65%. A 100% fabrication yield with cell-to-cell PCE variation of <5% is achieved. The module performance shows no loss from connection resistance compared to the discrete cells. Combined with an optimized visible light outcoupling (OC) structure, the ST-OPV module exhibited LUE=2.74±0.09% with APT=38.1±1.1% and PCE=7.2±0.1% under simulated AM 1.5G illumination at 1 sun intensity. With the combination of NIR absorbing BHJ, OC structure and minimized resistance loss in module construction, this is a significant improvement over previous reported ST-OPV module performance.

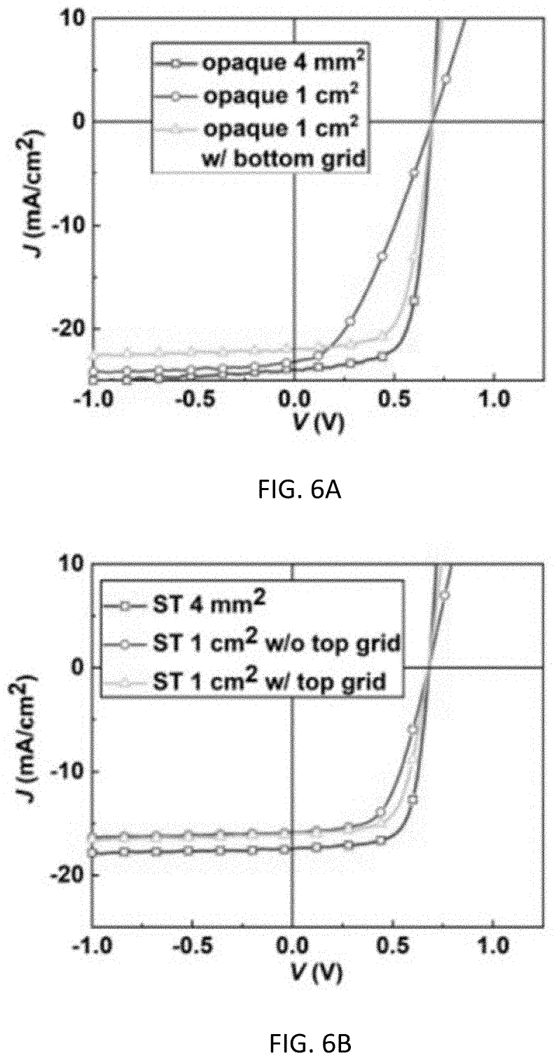

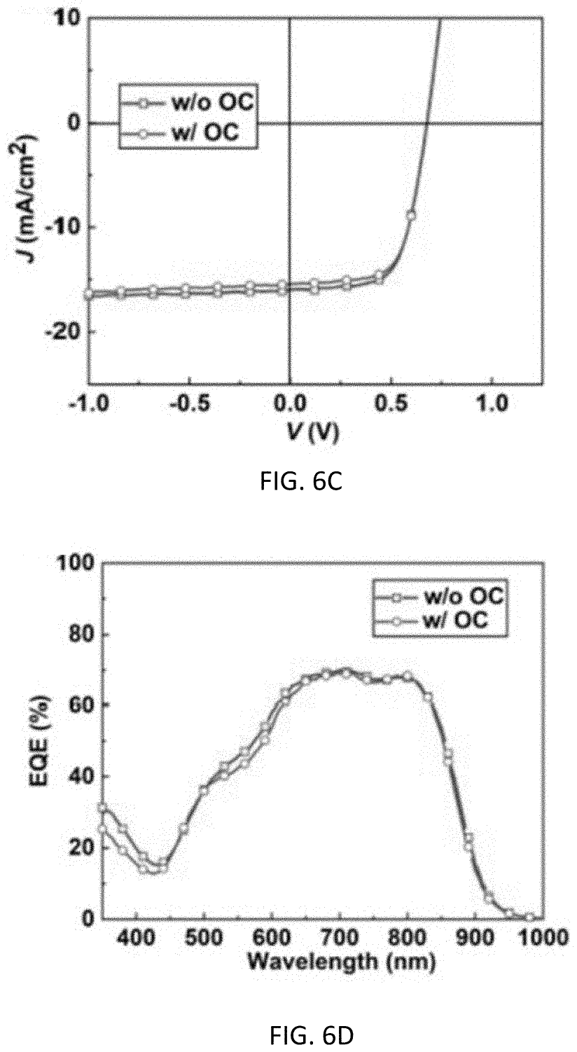

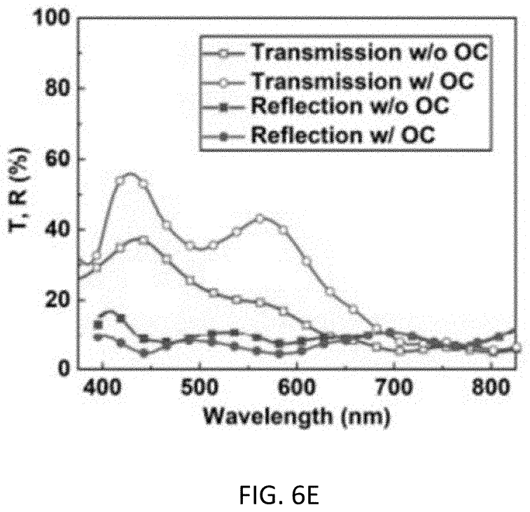

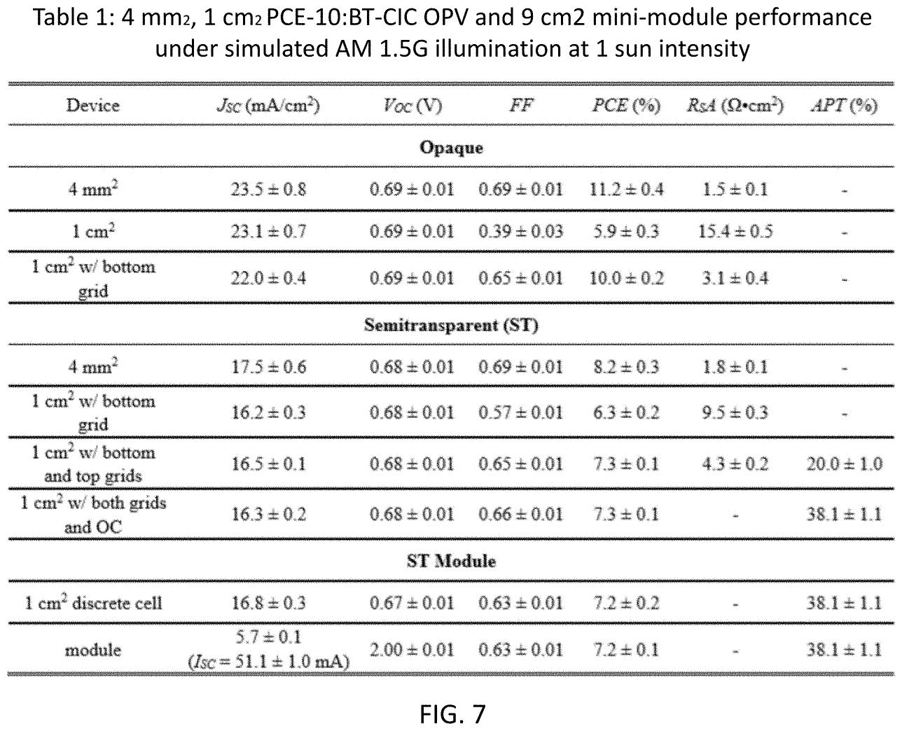

FIG. 2 shows a schematic illustration of the 1 cm² ST-OPV structure, which employed an 80 nm PCE10:BT-CIC (1:1.5 w/w) BHJ, with 30 nm thick ZnO and 20 nm thick MoOx as electron and hole transporting layers, respectively. To investigate the resistance loss from the bottom ITO cathode with area scaling, opaque OPV devices were fabricated with 100 nm thick top Ag anodes. The current density-voltage (J-V) characteristics are shown in FIG. 6A, with detailed performance parameters listed in the Table 1 of FIG. 7. The 4 mm² opaque device (red line with squares) has RSA=1.5±0.1 Ω·cm², however, the RSA increases to 15.4±0.5 Ω·cm² as the active area increases to 1 cm² (blue line with circles) due to the 15 Ω/sq sheet resistance of ITO, which results in a significant decrease in FF from 0.69±0.01 to 0.39±0.03. To reduce the RSA from ITO, a 500 nm thick Au surrounding and 50 nm thick Au grids were integrated onto the ITO cathode, as shown for the bottom electrode in FIG. 2. The nearly invisible grids were patterned into 20 μm wide stripes with 400 μm separation via photolithography. The grids reduce RSA of the 1 cm² opaque device (yellow line with triangles) to 3.1±0.4 Ω·cm², leading to FF=0.65±0.01. Although the short-circuit current density (JSC) is decreased from 23.1±0.7 mA/cm² to 22.0±0.4 mA/cm² because the Au grids partially block the light incident on the photoactive region, a significant increase in PCE from 5.9±0.3% to 10.0±0.2% is realized.

The 1 cm² ST-OPV devices with a 16 nm thick, semitransparent Ag anode were fabricated, with J-V characteristics shown in FIG. 6B and parameters listed in Table 1 of FIG. 7. Compared to 4 mm² devices (red line with squares) with RSA=1.8±0.1 Ω·cm², the 1 cm² ST-OPV with integrated bottom electrode (blue line with circles) shows RSA=9.5±0.3 Ω·cm², indicating that the resistance is mainly due to the ultrathin Ag anode which has sheet resistance of 6 Ω/sq. A layer of 100 nm thick Ag top grids was deposited with 20 μm grid width and 600 μm separation patterned using a 25 μm thick Kapton shadow mask. Compared to conventional metal shadow mask, the thin Kapton mask allows for ultrafine resolution patterning. The fabrication flow of the Kapton shadow mask is illustrated in in FIGS. 1A and 1B. The RSA of the 1 cm² ST-OPV (yellow line with triangles) is thus reduced to 4.3±0.2 Ω·cm², which leads to an increase in FF from 0.57±0.01 to 0.65±0.01, and the PCE from 6.3±0.2% to 7.3±0.1%.

The 1 cm² ST-OPV shown in FIG. 2 combines the bottom and top grid electrodes with the 4-layer OC structure comprising ZnS (30 nm)/MgF2 (100 nm)/4,4′-Bis(N-carbazolyl)-1,1′-biphenyl (CBP) (90 nm)/MgF2 (10 nm) at the top surface to improve visible transmission. The integration of grids on both electrodes affects 7% of the ST-OPV appearance. FIGS. 6C and 6D show the J-V characteristics and external quantum efficiency (EQE) spectra of the 1 cm² ST-OPV with and without the OC structure. Detailed parameters are provided in Table 1 of FIG. 7. The transmission and reflection spectra of the ST-OPV stack with and without the OC layers are plotted in FIG. 6(e). The OC structure significantly increases the transmission of ST-OPV in the visible, which results in an improved APT from 20.0±1.0% to 38.1±1.1%, while PCE=7.3±0.1% is maintained.

A small prototype module was than fabricated comprising nine, 1 cm² ST-OPVs cells with both grids and OC structures. As shown in FIG. 4, three discrete cells are series connected with a 0.3 cm interconnection distance to form a column, while three columns are separated by 0.25 cm, and are connected in parallel with the contact electrodes to construct the module. This design has a GFF=65%, which is limited by the width of bottom electrode Au surrounding bar, and the use of mechanical scribing to pattern the heterojunction layers. By increasing the Au side bar thickness, the width can be narrowed without affecting performance. Mechanical scribing can also be replaced with higher resolution laser scribing to further improve the GFF.

The fabrication yield of discrete cells is 100%. Under 1 sun illumination, the nine individual cells exhibit short-circuit currents of ISC=16.8±0.1 mA, VOC=0.67±0.01 V, FF=0.63±0.01. All the parameters have cell-to-cell variations of <5%. The PCE of the discrete cells ranges within 7.2±0.2%, as shown in FIG. 5A. FIG. 5B shows the current-voltage (IV) characteristics of a discrete cell and the module, with detailed parameters shown in Table 1 of FIG. 7. A module output power of 65±3 mW was obtained under simulated AM 1.5G at 1 sun intensity, with ISC=51.1±1.0 mA, VOC=2.00±0.01 V and FF=0.63±0.01, corresponding to an active area PCE=7.2±0.1. The module VOC is 0.5% less than the sum of the VOC of three individual cells, while ISC is within 1.5% deviation from the sum of three individual cells. Also, FF is the same as for the discrete cells, indicating that the resistance losses from electrodes and interconnections are minimal due to the metal girds and circuit layout. Combined with the optimized transmission APT=38.1±1.1%, a module LUE=2.74±0.09% was obtained. A photograph of the STOPV module is shown in FIG. 5C.

Although the module demonstrated has a GFF=65% which reduces the efficiency compared with that of the active area occupied by the individual cells, high resolution patterning as discussed above can significantly improve the GFF to realize a module efficiency approaching PCE=7.2±0.1% reported here. Furthermore, note that the ST-OPV module overcomes the efficiency loss from connection resistance, as more cells are connected even in opaque OPV modules. The results suggest that with the foregoing fabrication process, ST OPV modules with increased number of columns and rows can have an increased VOC and ISC without degradation of either FF or PCE.

Compared to 4 mm² devices, the dominant contribution from the ITO cathode and ultrathin Ag anode sheet resistance results in a significantly increased resistive loss in 1 cm² ST-OPV cells. By integrating Au grids onto the cathode and Ag grids onto the anode, the RSA is reduced such that the PCE loss is negligible. Furthermore, with the application of a series-parallel circuit layout, a 9 cm² active area prototype ST-OPV module with 100% discrete cell yield and a PCE variation within 5% across the module was demonstrated. The ST-OPV module exhibits PCE=7.2±0.1%, which has no loss compared to discrete cells performance, APT=38.1±1.1%, and LUE=2.74±0.09%. This demonstration provides a promising path for ST-OPV modules to achieve unlimited scalability with uncompromised module performance.

### Au Grids/ITO Cathode Fabrication

Glass substrates were cleaned with detergent and solvents before deposition. A 150 nm thick ITO layer was sputter-deposited at 1.72 Å/s in a high vacuum chamber (base pressure ˜10-7 Torr) and thermally annealed at 400° C. for 5 min in forming gas (5% H2+95% N2). The ITO was photolithographically patterned and wet etched using HCl:H2O (3:1) to define the square shaped cathode. The Au surrounding bars (0.5 mm wide, 200 nm thick on a pre deposited 10 nm thick Ti adhesion layer) were photolithographically patterned along three edges of the ITO cathode, and Au grids (20 μm wide, 400 μm separation, 45 nm thick with a 5 nm thick Ti adhesion layer) were patterned across the entire cathode. All Au and Ti layers were deposited via electron-beam evaporation at 5 Å/s. For the module, nine cathode squares were patterned into 3 columns and 3 rows.

### Kapton Shadow Mask Preparation

As described in FIG. 5, a 25 μm thick E-type Kapton foil was coated with 10 nm thick Ti/500 nm Al using electron-beam evaporation. A 100 μm thick PDMS (Sylgard 184, base-to-curing agent weight ratio=10:1) membrane was spun at 800 rpm on a 10 cm diameter Si handle and cured at 100° C. for 3 h. The Kapton foil with Al layer facing up was then attached to the PDMS membrane to eliminate curling. The top grid pattern (20 μm wide, 600 μm separation) was photolithographically defined on the foil. The foil is etched using Cl plasma (H2:Cl2:Ar=12:9:5 sccm, 10 mTorr chamber pressure, 500 W inductively coupled plasma (ICP) power, 100 W forward power for 1 min) to remove the Ti and Al layers and expose the Kapton. The 25 μm Kapton foil was then etched through using 02 plasma (02=20 sccm, 6 mTorr chamber pressure, 500 W ICP power, 100 W forward power for 40 min). Finally, the Kapton foil was detached from the PDMS membrane and soaked in buffered HF for 6 min to remove the remaining Al and Ti.

### Device Fabrication and Characterization

Glass substrates with a patterned cathode (ITO or Au/ITO) were cleaned using detergent and solvents followed by UV ozone exposure for 15 min before growth. The ZnO precursor solution was spin-coated onto the substrate at 3000 rpm and baked at 160° C. in air for 30 min. The PCE-10:BT-CIC solution was prepared in chlorobenzene with 10% chloroform at a concentration of 16 mg/mL and stirred overnight at 65° C., 350 rpm. After filtering through a 0.45 μm polytetrafluoroethylene filter, the solution was spin-coated at 2000 rpm on top of ZnO layer in ultrapure N2 (O2<0.1 ppm, H2O<0.1 ppm). Then the samples were transferred into a high vacuum chamber (base pressure ˜10-7 Torr) for thermal evaporation of 20 nm thick MoOx at 0.2 Å/s. For 1 cm² devices, the MoOx layer was deposited through a shadow mask. For the module fabrication, after MoOx deposition, the ZnO, BHJ and MoOx layers were mechanically scribed into nine units based on the cathode pattern to separate devices and expose one edge of each cathode for series connection. Then 16 nm thick Ag was thermally evaporated at 0.1 Å/s (100 nm Ag at 0.1-0.6 Å/s, for opaque devices) through a shadow mask followed by 100 nm Ag grid deposition at 0.1-0.6 Å/s through the Kapton shadow mask to construct the anode. The anode has a 1 cm² overlap with the cathode pattern to define the unit device area and to connect the unit cells in series along a column. The outcoupling structure was thermally evaporated in a high vacuum chamber (base pressure ˜10-7 Torr) at 0.5 Å/s for each layer.

The current density-voltage (J-V) characteristics and external quantum efficiency (EQE) of 4 mm² and 1 cm² devices were measured in a glovebox filled with ultrapure nitrogen (O2<0.1 ppm, H2O<0.1 ppm). The specific series resistance was obtained from fits from the linear region of the dark J-V curve. Light from a Xe lamp was filtered to achieve a simulated AM 1.5G spectrum (American Society for Testing and Materials, ASTM G173-03) whose 1 sun intensity was calibrated by a National Renewable Energy Laboratory certified Si reference cell to measure illuminated J-V characteristics. The EQE measurements were performed with a 200 Hz-chopped, monochromated Xe lamp. The illumination was focused to underfill the device area. For devices with grids, the beam underfills the area between grid lines. The current-voltage characteristics of the 9 cm² active area module were measured in air using a solar simulator with a 1000 W Xe lamp with an AM 1.5G filter (Oriel Instruments, Model 91191) whose 1 sun intensity was calibrated by a Si reference cell. The transmission spectra were measured using UV-vis spectrometer (Perkin-Elmer 1050). The reflection spectra are measured using an F20 Filmetric thin film measurement instrument integrated with a spectrometer and a light source from 395 nm to 1032 nm.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

What is claimed is:

1. An ultra-thin shadow mask, comprising:
a plastic foil including a plurality of apertures;
wherein the ultra-thin shadow mask is less than 25 μm thick; and
wherein the ultra-thin shadow mask has a feature size of between 1 μm and 100 μm.

2. The ultra-thin shadow mask of claim 1, wherein the plastic foil comprises Kapton.

3. The ultra-thin shadow mask of claim 1, wherein the shadow mask is configured for patterning flexible devices.

4. An apparatus for patterning an electrode using an ultra-thin shadow mask, comprising:
the ultra-thin shadow mask of claim 1;
a substrate configured to have an electrode disposed thereon positioned below the ultra-thin shadow mask; and
a patterning system including a material source and means for evaporating the material, positioned over the ultra-thin shadow mask, configured to pattern the electrode through the ultra-thin shadow mask.

5. The apparatus of claim 4, wherein the patterning system comprises a photolithography device.

6. The apparatus of claim 4, wherein the plastic foil comprises Kapton.

7. An organic photovoltaic (OPV) device, comprising:
at least one OPV cell comprising:
a first electrode including a first grid structure, the first grid structure having a feature size of between 1 μm and 100 μm;
a heterojunction under the first electrode;
a second electrode under the heterojunction including a second grid structure; and
a plurality of outcoupling layers over the first electrode.

8. The OPV device of claim 7, wherein the OPV device is semi-transparent.

9. The OPV device of claim 7, wherein the first grid structure is fabricated via the ultra-thin shadow mask.

10. The OPV device of claim 7, wherein the first electrode comprises an Ag layer about 16 nm thick.

11. The OPV device of claim 7, wherein the first grid structure comprises an Ag top grid having a grid width of between 5 μm and 50 μm, a grid separation of between 5 μm and 1000 μm, and a grid thickness of between 50 nm and 500 nm.

12. The OPV device of claim 7, wherein the heterojunction comprises poly[4,8-bis(5-(2-ethylhexyl)thiophen-2yl)benzo[1,2-b:4,5-b′]dithiophene-co-3-fluorothieno[3,4-b]thio-phene-2-carboxylate] (PCE 10) and (4,4,10,10-tetrakis(4-hexylphenyl)-5,11-(2ethylhexyloxy)-4,10-dihydro-dithienyl[1,2-b:4,5b′]benzodithiophene-2,8-diyl)bis-(2-(3-oxo-2,3-dihydroinden-5,6-dichloro-1-ylidene)-malononitrile) (BT-CIC).

13. The OPV device of claim 11, wherein the grid width is between 10 μm and 30 μm.

14. The OPV device of claim 11, wherein the grid thickness is between 50 nm and 150 nm.

15. The OPV device of claim 7, wherein the at least one OPV cell comprises a plurality of OPV cells arranged in a grid pattern.

16. The OPV device of claim 15, wherein the plurality of OPV cells are electrically connected in a series-parallel circuit layout.

17. The OPV device of claim 15, wherein the plurality of OPV cells are separated by an interconnection distance of 0.25 cm to 0.3 cm.

18. The OPV device of claim 7, wherein the first electrode is flexible.

19. An ultra-thin shadow mask fabrication method, comprising:
attaching a plastic foil to a handle substrate via an elastomer layer positioned over the handle substrate;
depositing a photoresist layer onto the plastic foil;
patterning the photoresist layer;
etching the plastic foil to create an ultra-thin shadow mask, wherein the ultra-thin shadow mask is less than 25 μm thick;
removing the photoresist layer; and
peeling the ultra-thin shadow mask off of the handle substrate.

20. The method of claim 19, further comprising:
depositing a hard etching mask layer onto the plastic foil prior to the step of depositing a photoresist layer onto the plastic foil;
patterning the hard etching mask layer with the photoresist layer;
etching the plastic foil layer through the patterned hard etching mask layer to create the ultra-thin shadow mask; and
removing the hard etching mask layer.
